(19) United States
(12) Patent Application Publication
(10) Pub. No.: US 2019/0162787 A1
(43) Pub. Date: May 30, 2019

(54) CIRCUIT BREAKER LOCATOR AND TESTER

(71) Applicant: Maxim Hurwicz, Stanchfield, MN (US)

(72) Inventor: Maxim Hurwicz, Stanchfield, MN (US)

(21) Appl. No.: 16/202,045

(22) Filed: Nov. 27, 2018

Related U.S. Application Data
(60) Provisional application No. 62/590,834, filed on Nov. 27, 2017.

(51) Int. Cl. G01R 31/327; H02H 1/00; H03K 17/081

(52) U.S. Cl. CPC G01R 31/3277; H03K 2017/0806; H03K 17/08108; H02H 1/0007

(57) ABSTRACT

A circuit breaker locator/tester is made more effective and efficient by appropriately dealing with inherent temperature variations. During operation of the circuit breaker locator/tester, large amounts of current are pulsed through various components, resulting in significant heating effects. These pulses of large amounts of current are generated in relatively brief time periods. While components are designed to manage and deal with various heating effects, excessive heating can degrade performance and efficiency. Various monitoring devices and heat anticipation systems are included within the locator/tester to deal with these conditions. In certain embodiments, temperature monitoring components are included, which provides a clear indication of sensed temperatures at specific locations within the device. In addition, systems are also provided to concurrently monitor operation of the device and provide operational control so that undesirable operating conditions are not encountered. Using these operational monitoring systems, appropriate delays can be incorporated which will naturally allow for heat dissipation.

The present application claims priority to U.S. Provisional Application No. 62/590,834, filed Nov. 27, 2017, which is incorporated herein by reference.

### BACKGROUND

The present disclosure is directed to an improvement in a circuit breaker locator and tester. More specifically, the circuit breaker locator and tester has an improved ability to manage the strain of high current and heat generated during the testing process.

Circuit breaker locator and testers have been available for a number of years, and are valuable tools for use by those installing and evaluating electrical systems. Two examples are set forth in U.S. Pat. No. 7,713,428 “PORTABLE CIRCUIT INTERRUPTER SHUTOFF TESTING DEVICE AND METHOD”, and U.S. Pat. No. 7,199,587 “PORTABLE CIRCUIT INTERRUPTER TESTER AND METHOD”, the subject matter of which is incorporated herein by reference. In use, a circuit breaker locator/tester creates a brief surge of current that passes through various components and which generates heat within the device. This heat is then naturally dissipated over a period of time. However, if the circuit breaker locator/tester is used multiple times within a short time period, heat will not sufficiently dissipate, creating a cumulative heat build-up and potential problems. More specifically, this heat build-up can be destructive to the parts of the device and can possibly effect accuracy/efficiency of operation. Somewhat akin to tension in the Earth's crust going unnoticed but at some subsequent time being released in an undersea earthquake and only be expressed by an inevitable, disastrous and quite noticeable tsunami some distance way.

In one example, a switching element, e.g. a thyristor such as a power silicon controlled rectifier (SCR) which is often used in a portable circuit breaker locator/tester and can switch less current as its temperature increases. Stated differently, the SCR's current carrying capability is inversely related to temperature as shown in FIG. 2 (which is a reproduction of FIG. E6.10 from the Teccor Thyristor Product Catalog for SCRs, from Littelfuse, Inc.). When used in a circuit breaker locator/tester, it is thus important and extremely beneficial to keep the switching element within its safe operating temperature relative to the amount of current it is switching.

Also, the locating/testing device will typically include a power resistor which is used for various purposes during the testing cycle. This power resistor also has a wattage rating, which essentially indicates how much heat it can withstand before it is destroyed or degraded. Naturally, it is very desirable to keep the operating conditions within acceptable ranges for this resistor, to avoid damage and maintain proper operation.

It is well recognized that a power resistor tends to burn up and create an open circuit, similarly to a fuse, when subjected to failure conditions (i.e. subjected to excess power levels and/or overheating). Conversely, when an SCR is used as a switch and it is subjected to excessive power and/or heat, it will burn up and create a short or closed circuit. Obviously, this can be dangerous and possibly life threatening.

A relatively unique situation with the circuit breaker locator/tester device is that it is creating heat within a very short period of time. For example, heat can be generated in a fraction of a single cycle of 120 VAC. Further, within the locator/tester device heat propagates from the heat generating points relatively slowly. Thus repeated usage can create accumulated heat before it is apparent to a user. For instance, if one is using an SCR for the switching element, the actual switching is occurring within a part which has a significant plastic shell. Consequently, it takes a length of time for the heat to emanate from the center to the surface of the SCR (i.e. to the outer surface of the plastic shell). Likewise, if a power resistor is being used for determining the current of the test cycle, it takes a length of time for the heat to emanate from the resistance wire through whatever coating or insulation is on the resistor before it will reach the resistor's surface.

This device is also unique in that it is carrying what would usually be considered to be tremendous amounts of current. For instance, it may carry 600 amps which may appear to exceed the ratings of the parts which carry the current. However, because the device's test cycle time is a fraction of a second (e.g. one half cycle of a standard 120 VAC 60 Hz power signal), it is only actually carrying 1/120th of that 600 amperes or the equivalent of 5 amps. The components of the device are selected to be able to carry such brief surges in current, but at the same time their current carrying capacity is inversely proportional to their temperature.

In addition to the SCR and power resistor, the other parts of the circuit breaker locator/tester device can operate improperly if subjected to excessive amounts of heat. Thus, the heat generated during testing can adversely affect many components.

Also, as heat is dissipated through the case of the device, it is less comfortable for a user to hold. Clearly, this is undesirable as it may lead to user injury.

Thus it would be beneficial to have a method for limiting the amount of heat generated to within a comfortable, safe operating area (SOA).

### SUMMARY

The desire is to disable the circuit breaker locator/tester device when a certain amount of heat has been generated, and then to enable the device again when it has cooled to within a safe operating temperature. Also it is desirable, although not necessary, to give the user some indication when the device is ready to use, or has paused to cool, so they won't think the device is simply out of order.

In order to address the above-outlined issues related to heating, the systems and method described herein provide a dual approach to heat management. Generally speaking, a temperature sensor is included within the device which monitors temperature at a predetermined location or area. This information is then provided to a controller which can decide whether the device should be shut down or paused for a period of time, or should continue to be operational. In addition, the controller circuit is capable of monitoring the frequency of operation, and using this information to control operation in a manner which will minimize heating effects. The monitoring of operation is carried out in a number of ways, including modeling based upon a parallel charge capacitor, or maintenance of a counter which tracks the operation time of the device. Based upon this information, a subsequent timing or delay sequence can be implemented, which will limit operation and avoid undesirable conditions.

### BRIEF DESCRIPTION OF THE DRAWINGS

FIG. 1 is a flow chart showing steps involved in one embodiment of the circuit breaker locator/tester presented herein.

FIG. 2 illustrates the relationship between allowable current and case temperature of an SCR.

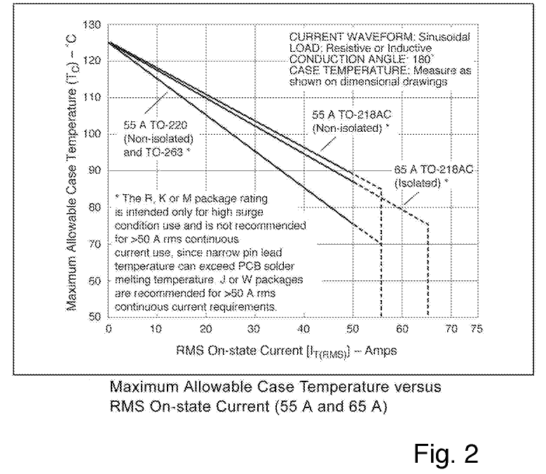

FIG. 3 sets forth a simplified circuit diagram of an embodiment of the invention including a temperature sensor and an optional capacitor/resistor network.

FIG. 4 presents an alternative flow chart, illustrating an alternative method of efficiently operating the circuit breaker locator/tester.

### DETAILED DESCRIPTION

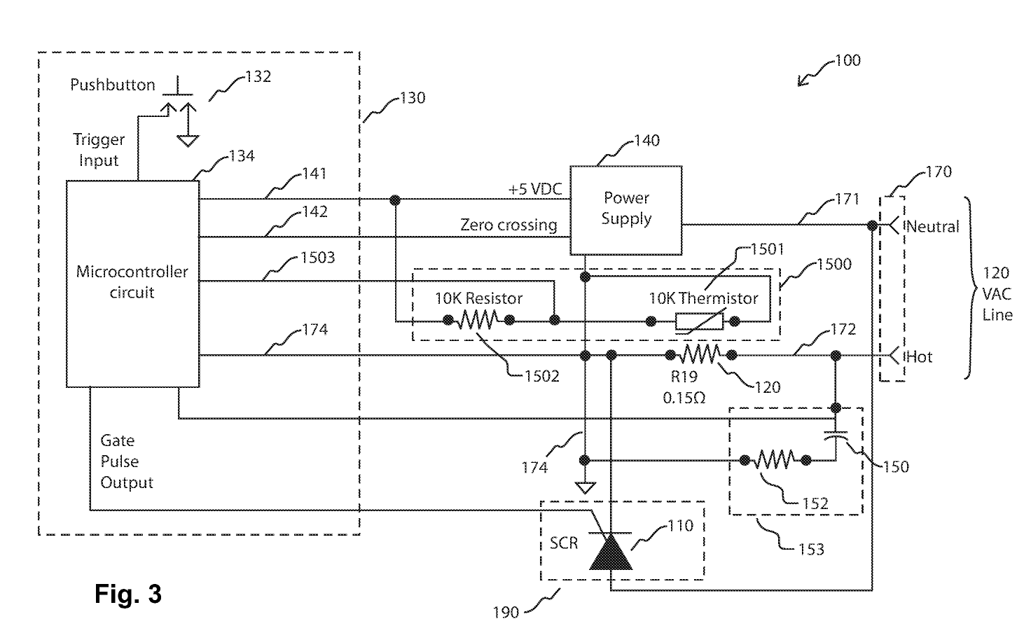

As shown in FIG. 3, the circuit breaker tester/locator device 100 includes a power supply 140, micro-controller circuit 130, thyristor switch (e.g. SCR) 190 and load resistor 120. Micro-controller 134 can be a programmable flash-based part, such as a PIC12F1840 or a PIC16F1825, selection of which depends on the selected set of functions required. As will be recognized, there are many micro-controllers which can perform the tasks described herein. It is intended that any of these alternative micro-controllers are included within this disclosure, in addition to other types of controllers, application specific integrated circuits (ASICs), microprocessors, etc.

To deal with heat related issues, a temperature sensor circuit 1500 is also included, which is a simple potential divider circuit comprising a thermistor 1501 and a resistor 1502, which supplies micro-controller 134 with a voltage 1503 indicative of sensed temperature. For example, thermistor 1501 could be a 10 kΩ thermistor and resistor 1502 could be a resistor of 10 kΩ. In this configuration, the output voltage 1503 at a given baseline temperature will be half the supply voltage. When the resistance of thermistor 1501 changes due to changes in temperature, the fraction of the supply voltage across the thermistor also changes producing an output voltage 1503 that is proportional to the fraction of the total series resistance between the output terminals. Thermistor 1501 may be in physical contact with the power resistor through an electrically insulating but thermally transmissive medium, or not in direct contact but positioned to receive heat generated nearby.

As will be appreciated, there are many variations of temperature sensing circuits, thus circuit 1500 is simply one example. Likewise there are various types of temperature sensors available for use, such as Negative Temperature Coefficient (NTC) thermistors or semiconductor-based temperature sensors, each of which has their own advantages and circuit designs. It is further contemplated that any of these devices can be used to carry out the principles of the disclosed embodiments.

Temperature sensor circuit 1500 is used to detect the ambient temperature at a particular location within the device. Clearly, this information can be used to help determine if the device is operating within or outside of the safe operating area (SOA). That said, heat can build up in the load resistor during repeated uses which will not be immediately apparent or detectable by the temperature sensor. Unfortunately some span of time is typically required for the thermistor to become measurably heated and give an indication of the heat that is on its way. Additionally, once heat reaches the load resistor's surface and spreads throughout the locator/tester device, it can be destructive to the device's parts. Likewise there can be variations in the length of time required to dissipate the heat generated within the device. For instance, heat dissipation can vary depending on whether the device is in open air or in one's pocket.

While a temperature sensor, such as a thermistor, can be used to indicate when the device has cooled enough to be used again, it may not always respond fast enough to prevent a buildup of heat. As suggested above, if the device is triggered many times in quick succession heat buildup will occur, but will not be immediately detectable. Thus, it is desirable to have a supplemental approach to temperature sensing, and to provide real-time temperature monitoring.

FIG. 3 also shows power supply 140 which includes DC output 141 and zero cross connection 142 and controller circuit 130 which includes trigger input pushbutton switch 132 and micro-controller 134. As also illustrated, the connection to the circuit of the instantaneous circuit breaker 170, neutral prong 171, hot prong 172 and internal hot connection 174 which is also used as the low-voltage ground.

Some embodiments include load resistor 120 (e.g., resistor/fuse R19), which acts as a high-current load (e.g., 0.15 ohms, 50 watts). In some embodiments, this resistor 120 acts as a fuse that opens if a high current is seen for too long a period, such as a failure of SCR 110 that shorts it, or a failure of controller circuit 130 that turns the SCR 110 on for too long a period of time.

Again, tester 100 includes one or more controllers 130 that stop conduction of the respective trip-testing function at a predetermined point in time that is related to the specified trip time of the circuit interrupter being tested. As will be further discussed below, operational options (such as the number of cycles per test or responses to thermistor input) will be controlled through programming the micro-controller 134.

For example, for testing an instantaneous-trip function of a circuit interrupter that specifies that it is to trip within 1/20 of a second (3 full cycles of 60 Hz AC), the switching element 110 conducts for a half cycle in some embodiments (in other embodiments, two, three, four, five, or six half cycles of conduction are used). In some embodiments, non-consecutive half cycles are used.

For the above embodiments, resistor 120 is about 0.15 ohms, which limits the short-circuit current to about (110 volts to 120 volts)/0.15 ohms, which equals about 733 to 800 amperes. Some embodiments will omit the current-limiting resistor 120, and instead will count on the internal resistance of the electronic switch 110 (or will incorporate a resistance into switch 110) along with the resistance of the wiring to limit the current during the half cycle(s) of switch 110 being activated.

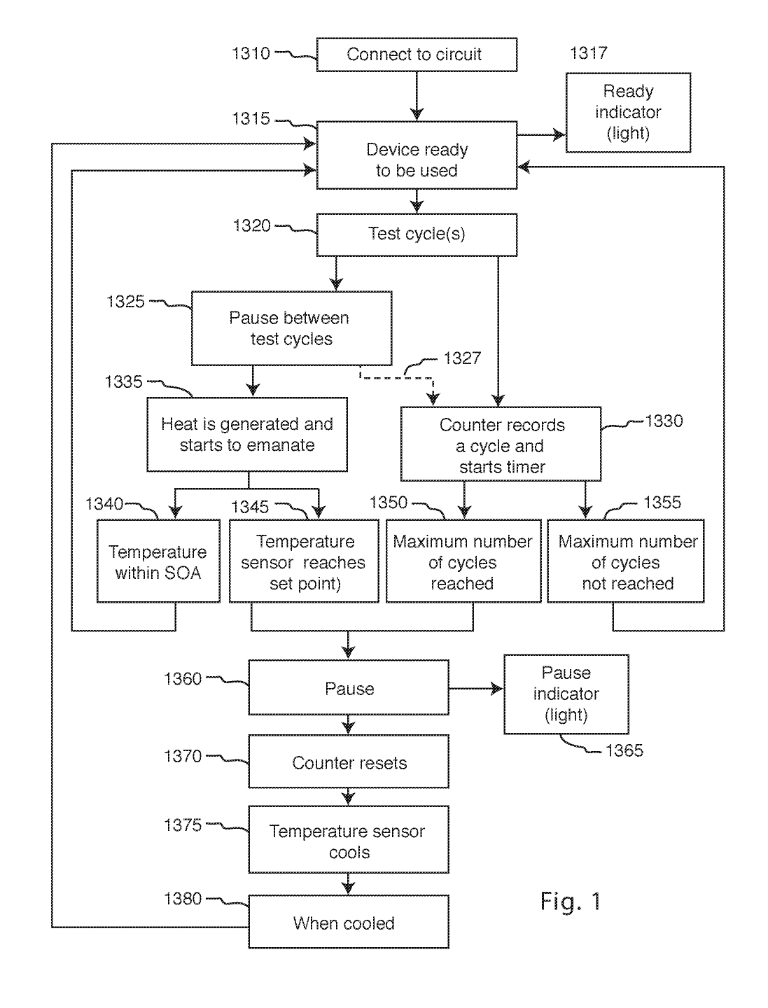

FIG. 1 is a flow chart showing one embodiment of the steps to operate locating/testing device 100. The device is connected to the circuit of a circuit breaker 1310. If it is ready to use 1315 an optional indicator such as an LED can illuminate to show the ready state 1317. Then the device is put through one or more test cycles 1320. A pause or delay between cycles 1325 will typically allow heat to emanate. If the temperature remains within the SOA 1340 then the device is ready to be used again 1315. Heat is generated and if the temperature sensor responds to suggest a future overheating situation is anticipated 1345, then the device is paused 1360. The micro-controller can be programmed to be disabled with a forward-looking preset temperature threshold which is lower than an actual overheating temperature.

If one is using other means, such as a counter, to anticipate over-heating from repeated uses, the counter records each cycle and starts a timer with the first cycle 1330. After a predetermined number of cycles have occurred within a given time period 1350 the device would pause 1360. Optionally a pause or delay between cycles 1325 will typically allow heat to emanate as shown with dashed line 1327. This allows the heat to emanate and reach the temperature sensor as in step 1335. If the maximum number of cycles within the given time period has not been reached 1355, then the device is ready to be used again 1315. Such a counter can work in isolation or in combination with a temperature sensor. If there is no temperature sensor then one can simply use empirical testing to define a pause of sufficient length to allow the device to stay within the SOA.

Either state (either the temperature sensor anticipating overheating 1345 or the counter reaching a predetermined number of cycles 1350), can cause the device to pause 1360. An optional indicator, such as an LED, can communicate to let the user know the device is paused 1365. The counter resets after a given time period 1370 and the temperature sensor cools 1375 giving the device time to achieve a safe operating temperature. When such a state has been achieved 1380 the optional pause indicator 1365 is turned off and device is re-enabled so it is ready to be used again 1315.

The idea is not simply to respond to overheating but to be able to anticipate a possible future overheated state and to accommodate cooling the device preemptively so it can operate within its safe operating area. Additionally, the temperature sensor circuit 1500 (as shown in FIG. 3) allows for controlling the device's usage in various situations. For instance, if the user has put the device into an insulated area such as a coat pocket where it cools more slowly, or if it is placed where it can cool more rapidly such as in free air, different types of delay may be required and/or appropriate. Also, it may be of use to have a predetermined time delay between test cycles which could allow the emanation of heat, for example from the load resistor, to reach the temperature sensor, as shown in FIG. 1, steps 1325 and 1335.

When the circuit breaker locator/tester device 100 is used, it attempts to trip a breaker by creating a brief current surge. If the breaker does not trip then the current surges for the entire period that the tester is on. If the breaker trips faster than the duration of the tester's programmed on-time, then less total current actually flows. Using a temperature sensor circuit 1500 with a delay can track such current via the heat created.

Since heat buildup in the tester is proportional to the total current that flows there is an advantage to measuring the actual current flow. This can be done various ways such as via measuring the on-time or by charging and discharging a resistor-capacitor network 153 having a charge capacitor 150 and a discharge resistor 152 (as shown in FIG. 3) while the test cycle(s) are in progress. On the other hand, a designer may find advantage in simply counting whole numbers of on-cycles or number of test periods instead. These are just a few ways a designer can anticipate an overheating situation to pause the device so it has a chance to cool and to also allow time for the generated heat to reach a temperature sensor 1501 which can signal the microcontroller 134 to pause the device 100 until it has cooled to a safe operating temperature.

Likewise, even if one is tracking current or number of cycles, if the temperature sensor circuit 1500 senses an overheating situation it can independently pause the device 100. This could occur, for instance, if the device 100 were in a hot environment. So the device can have one temperature setting for pausing and a different temperature setting for being re-enabled.

One can also have a default pause or delay before and/or after a test cycle to allow the heat generated to reach the temperature sensor 1501 and to allow the device to cool. The combination of a delay and a temperature sensor 1501 can then control when the device 100 is allowed to be used again. This combination of a delay and a temperature sensor can operate with or without an associated counter or other ways of tracking usage.

If one empirically determines the amount of heat generated and the amount of time it takes for the heat to reach the temperature sensor 1501, one can incorporate a delay of that amount of time between uses. For instance, if it takes 5 seconds for the heat to reach and heat up the sensor, then there could be a delay of 5 seconds between uses. Typically such an amount of time is between 1 and 10 seconds. Such a delay could come after the device is connected to the circuit of the circuit breaker but before it is possible to trigger the test cycle of the device or the delay could come after triggering or some combination of delays before and after the test cycle.

The foregoing is presented simply as one example of a way to perform the desired improved functions to the circuit breaker locator/tester 100. Those skilled in the art will understand there are other ways to accomplish such things as monitor temperature, track cumulative on-time, count number of times the device is cycled and allow pausing and re-enabling of a device and other functions mentioned in this disclosure. This may also include carrying out certain steps in a different order, or concurrently.

In another embodiment, the heat build-up in the power resistor 120 and SCR 110 is modeled by means of a stored charge on a modeling capacitor 150 as shown in sub-section 153 in FIG. 3. In use, monitoring capacitor 150 will be charged during the testing stage of the tester 100. This modeling or “memory” capacitor 150 continues to model the heat build-up and cooling off even when power has been removed (for instance, when the device has been unplugged or the circuit breaker supplying power has been tripped). As mentioned above, the testing phase is relatively short, thus when power is no longer presented, the modeling capacitor will then discharge at a predetermined rate.

In this embodiment, the capacitor 150 charges a little bit every time the device is activated, and the capacitor will discharge at a controlled rate through a resistor 152. The rate of discharge of the capacitor 150 models the cooling down of the power resistor. The charge will persist through power-downs, so it fills the function of a non-volatile memory and timer when the microcontroller is not running.

Operational options (such as the number of half cycles of virtual short-circuit) is controlled through programming the microcontroller. Optionally, there can be an on-board option selection switch to select the number of on cycles.

The foregoing is presented simply as one example of a way to perform the desired functions of temperature management. Those skilled in the art will understand there are other ways to monitor temperature, track cumulative on time or current and allow pausing and reenabling of a device.

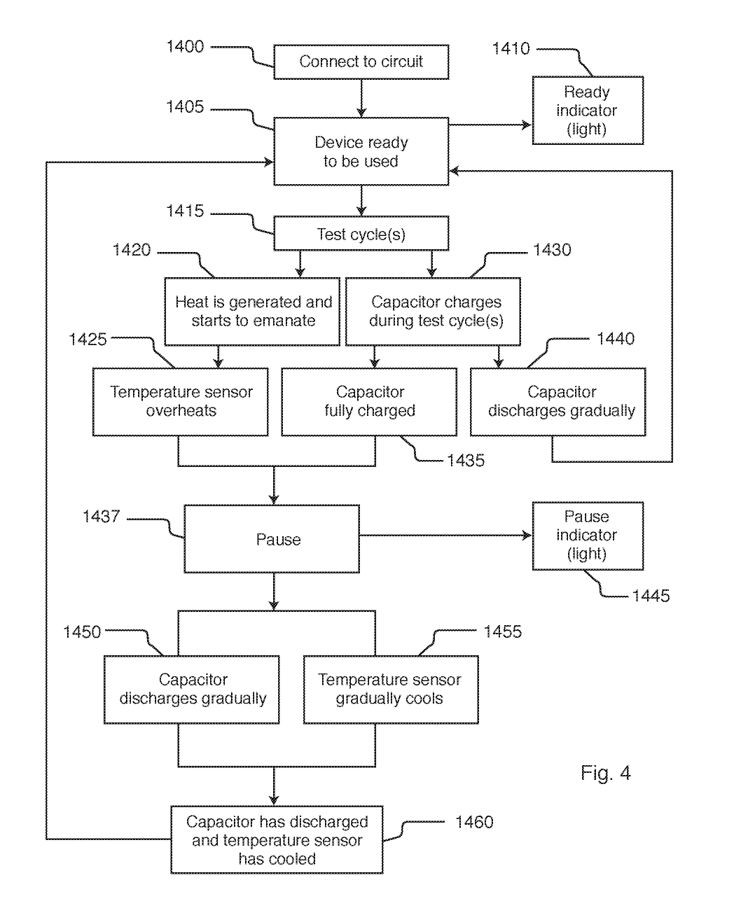

FIG. 4 is a flow chart showing an alternative approach to execute the functions of the testing device. The device connected to a circuit 1400. If it is ready to use 1405 an indicator such as an LED can illuminate to show a ready state 1410. Then the device is put through one or more test cycles 1415. Heat is generated 1420 and if the temperature sensor responds 1425, then the device is paused 1437. At the same time a capacitor is being charged 1430. If the capacitor is not fully charged (or charged to a predetermined state) in the first cycle 1415 and 1430 then the device is ready to be used again 1405 during which time the capacitor discharges gradually 1440. Additional test cycles will charge the capacitor further 1405, 1415 and 1430. When the capacitor is fully charged (or charged to a predetermined state) 1435, the device is paused 1437.

Either state, either the temperature sensor overheating 1425 or the capacitor reaching the charged state 1435, can cause the device to pause 1437. An optional indicator, such as an LED, can communicate to let the user know the device is paused 1445. The capacitor discharges 1450 and the temperature sensor cools 1455 giving the device time to achieve a safe operating temperature 1460. When such a state has been achieved the optional pause indicator can turn off (not shown) and the ready to use indicator can be activated 1410. Now the user can use the tester again 1405.

Again, the basic idea is to be able to anticipate an overheated state and to accommodate cooling of the device so it can operate within its safe operating area. One could have such a setup without a temperature sensor being incorporated. In such a case one would simply trust in the capacitor/resistor or other control means to control the activation and pausing by anticipating what heating might occur during usage. Additionally, having the temperature sensor allows for controlling the device's usage in various situations, for instance, if the user puts the device into an insulated area such as a coat pocket where it cools more slowly or if it is placed where it can cool more rapidly such as in free air. So while having a means to anticipate the heating is essential, in actual practice the heat sensor may be deemed unnecessary. Likewise, if the temperature sensor can be positioned such that it can sense temperature changes relatively instantaneously, such as if it were wrapped in the resistance wire of the power resistor, then the sample capacitor/resistor may be deemed necessary. Also, it may be of use to have predetermined time delay between test cycles which could allow the emanated heat to reach the temperature sensor. This and other such variations and combinations are well known to those skilled in the art.

When the circuit breaker locator/tester is used it attempts to trip a breaker by creating a brief current surge. If the breaker does not trip then the current surges for the entire period that the tester is on. If the breaker trips faster than the duration of the tester's maximum on time, then less total current actually flows. Since heat buildup in the tester is proportional to the total current that flows there is an advantage to measuring the actual current flow. This can be done various ways such as via measuring the time on or by charging a capacitor while the test is in progress. On the other hand, a designer may find advantage in simply counting the number of on-cycles or number of test periods instead. These are just a few ways a designer can anticipate an overheating situation to pause the device so it has a chance to cool and to also allow time for the generated heat to reach a temperature sensor which can also serve to pause the device until cooled to a safe operating temperature.

Likewise, if the temperature sensor senses an overheating situation it can independently pause the device. This could occur, for instance, if the device were in a hot environment.

One could also have a default pause or delay after a test cycle to allow the heat generated to reach the temperature sensor and/or to allow the device to cool. If such a temperature sensor is incorporated then said temperature sensor can then control when the device is allowed to cycle again.

Obviously, if one is using a different way to anticipate repeated uses, such as a counter, then the device would pause after a predetermined number of cycles within a predetermined amount of time. This allows the heat to emanate and reach the temperature sensor. Such a counter can work in isolation or in combination with a temperature sensor. If there is no temperature sensor then one can simply use empirical testing to define a pause of sufficient length to allow the device to cool and stay within the SOA. A method, such as a counter, could include a power source such as a battery, so that it is not reset simply by being plugged out and back in or incorporate a type of memory which is retained in such a situation.

Alternatively, if one determines the amount of heat generated and the amount of time it takes for the heat to reach the temperature sensor, one can incorporate a delay between uses. For instance, if it takes 5 seconds for the heat to reach and heat up the sensor, then there could be a delay of 5 seconds between uses. Such a delay could come after the device is connected to the circuit of the circuit breaker before it is possible to trigger the test cycle of the device or the delay could come after triggering or some combination of part of the delay before and part of the delay after the test cycle. Likewise there could be variable delay lengths depending on the number of test cycles or length of on time or actual measurement of current passed.

A display, such as a series of lights, could show the delay time elapsing so the user will have an indication of when the device will be ready for use.

As outlined above, the circuit breaker locator/tester 100 comprises a current anticipating portion and real time temperature sensing portion which work cooperatively and independently to control pausing and enabling the device so as to keep the tester within a comfortable safe operating temperature. Variations have also been presented, such as a counter or time delays, or controlled capacitor discharge, which can also perform the job of anticipating and handling heat generation to keep the tester within a comfortable safe operating temperature.

As set forth above, the following components have been discussed and described:
100 Tester device
110 Switching element (e.g. an SCR or thyristor)
120 Load resistor (power resistor) (e.g. resistor/fuse R19)
130 Micro-controller circuit (controller circuit)
132 Trigger input/Pushbutton (e.g. a momentary-contact switch)
134 Micro-controller
140 Power supply
141 DC output
142 Zero cross connection
150 Charge Capacitor
152 Discharge Resistor
153 RC network
170 Connection to the circuit of the instantaneous circuit interruptor
171 Neutral prong
172 Hot prong
174 Internal hot connections (which is also used as the low-voltage ground)
190 Electronic switching element(s) (thyristor switch)
1300 Flow chart
1310-1380 steps in the flow chart of FIG. 1
1400-1460 steps in the flow chart of FIG. 4
1500 temperature sensor circuit (potential divider circuit)
1501 Thermistor (e.g. 10K)
1502 Resistor (e.g. 10K)
1503 Output voltage to measure temperature

Having thus described several illustrative embodiments, it is to be appreciated that various alterations, modifications, and improvements will readily occur to those skilled in the art. Such alterations, modifications, and improvements are intended to be part of this disclosure, and are intended to be within the spirit and scope of this disclosure. While some examples presented herein involve specific combinations of functions or structural elements, it should be understood that those functions and elements may be combined in other ways according to the present invention to accomplish the same or different objectives. In particular, acts, elements, and features discussed in connection with one embodiment are not intended to be excluded from similar or other roles in other embodiments. Accordingly, the foregoing description and attached drawings are by way of example only, and are not intended to be limiting.

1. A circuit breaker locator/tester for performing evaluation of an existing electrical system, comprising:
a triggering circuit comprising a switch and a load coupleable to the existing electrical system, wherein the triggering circuit is configured to cause a testing surge to be generated in the existing electrical system when the switch is activated, wherein the switch and the load are also subject to the testing surge;
a temperature sensor for monitoring the temperature within the locator/tester at a location and providing an output indicative of the monitored temperature;
a monitoring circuit for monitoring operation of the triggering circuit to determine if excess heat conditions exist based upon a predetermined set of operating conditions; and
a disable circuit in communication with the monitoring circuit and the temperature sensor to disable the trigger circuit for a predetermined period of time if the excess heat conditions exists or the temperature sensor indicates that the heat at the predetermined location is above a predetermined level.

2. The circuit breaker locator/tester of claim 1 wherein the monitoring circuit comprises a microcontroller which will monitor the amount of time the triggering circuit is subject to the testing surge, which is indicative of the amount of current carried by the load and the switch.

3. The circuit breaker locator/tester of claim 1 wherein the monitoring circuit comprises a capacitor configured to charge when the testing surge is present, and thus provide a thermal model of the switch and the load.

4. The circuit breaker locator/tester of claim 2, wherein the temperature sensor output is communicated to the microcontroller, and wherein the microcontroller is capable of determining if the temperature at the location is above the predetermined level, and when the temperature is above the predetermined level, the microcontroller is capable instituting the delay.

5. The circuit breaker locator/tester of claim 4 wherein the microcontroller will generate a disable signal if the temperature signal is above the predetermined level, thereby causing the delay circuit to institute the delay.

6. The circuit breaker locator/tester of claim 2 further comprising a manually operated activation switch coupled to the microcontroller to initiate a testing cycle and cause the test surge to be generated.

7. The circuit breaker locator/tester of claim 1 wherein the period of time for the delay is between 1 and 10 seconds.

8. The circuit breaker locator/tester of claim 1 wherein the predetermined temperature is selected such that the disable circuit will disable before a true overheating condition exists.

9. The circuit breaker locator/tester of claim 6 wherein the microcontroller has a counter for monitor the amount of time the triggering circuit is subject to the testing surge, and the number of test cycles initiated.

10. The circuit breaker locator/tester of claim 1 wherein the temperature sensor is a thermistor.

11. A circuit breaker locator/tester device attachable to an installed electrical system, comprising:
a microcontroller;
a load circuit coupled to and controlled by the microcontroller, wherein the load circuit comprises a power switch and a load resistor and wherein activation of the power switch generates a testing cycle which causes a testing surge of current to be generated within the installed electrical system when attached thereto; and
a temperature sensor for monitoring the temperature at a location within the device, the temperature sensor providing a temperature signal to the microcontroller indicative of the temperature at the location;
wherein the microcontroller will monitor the operation of the load circuit and the temperature sensor and will delay activation of the power switch if the temperature sensor indicates that the temperature at the location is above a predetermined temperature level, or the load circuit has operated outside a predetermined set of preferred operating parameters.

12. The circuit breaker locator/tester of claim 11 wherein the power switch is a thyristor capable of transmitting in one direction and the load is a load resistor.

13. The circuit breaker locator/tester of claim 12 wherein the location within the device is proximate the load resistor or the thyristor or both.

14. The circuit breaker locator/tester of claim 12 wherein the monitored operation of the load circuit includes monitoring the time the testing surge is present and the number of test cycles that have been completed within a recent time period.

15. The circuit breaker locator/tester of claim 11 further comprising a power supply receiving a line signal from the installed electrical system and providing a low voltage signal to the microcontroller indicative of the frequency of the line signal, wherein the microcontroller can operate as a counter to monitor the time the testing surge is present.

16. The circuit breaker/tester of claim 11 wherein the delay is between 1 and 10 seconds.

17. The circuit breaker locator/tester of claim 14 wherein the predetermined set of operating parameters comprise a combined predetermined amount of time the testing surge is present for each test cycle and number of test cycles within a the recent time period.

18. The circuit breaker locator/tester of claim 11 wherein the predetermined set of operating parameters comprise a predetermined number of test cycles within the recent time period.

19. The circuit breaker locator/tester of claim 11 wherein the delay will continue until the temperature sensor has returned to a level below the predetermined level.

20. The circuit breaker locator/tester of claim 11 further comprising a resistor/capacitor network coupled to the load circuit such that the capacitor will charge during the testing surge and will discharge when the testing surge is not present, the resistor/capacitor network further configured to reach a predetermined threshold charge when the load circuit has operated outside the predetermined set of preferred operating parameters, and wherein the microcontroller will monitor the charge on the capacitor and will delay operation based upon said monitored charge.

21. The circuit breaker locator/tester of claim 20 wherein the delay will continue until the capacitor has discharged to below the predetermined threshold charge.

22. The circuit breaker locator/tester of claim 20 wherein the delay will continue for a predetermined period of time.

23. The circuit breaker locator/tester of claim 22 wherein the predetermined period of time is between 1 and 10 seconds.

24. The circuit breaker locator/tester of claim 15 wherein the counter is used to determine if the load circuit has operated outside the predetermined set of preferred operating parameters.

25. The circuit breaker locator/tester of claim 24 wherein the delay will continue for a predetermined period of time.

26. The circuit breaker locator/tester of claim 24 wherein the delay will continue until the temperature sensor has dropped to below a predetermined target level which is different than the predetermined temperature level.

27. The circuit breaker locator/tester of claim 24 wherein the predetermined set of operating parameters comprise a combined predetermined amount of time the testing surge is present and number of test cycles within a the recent time period.

28. The circuit breaker locator/tester of claim 11 wherein the predetermined set of operating parameters comprise a predetermined number of test cycles within the recent time period.

29. The circuit breaker locator/tester of claim 11 wherein overheating will occur at an overheating temperature and the predetermined temperature level is set at a temperature below the overheating temperature.

30. The circuit breaker locator/tester of claim 29 wherein the predetermined temperature is based upon a thermal model of the device.

31. The portable handheld circuit breaker locator/tester of claim 11 where in the microcontroller will further insert a testing delay between testing cycles.

32. The circuit breaker locator/tester of claim 11 wherein the microcontroller, load circuit and temperature sensor are all contained within a housing, thus making the locator/tester easily portable.

33. A portable handheld circuit breaker locator/tester easily attachable to an installed electrical system, comprising:
a housing sized and configured to be portable;
a microcontroller contained within the housing;
a load circuit contained within the housing, the load circuit coupled to and controlled by the microcontroller, wherein the load circuit comprises a power switch and a load resistor and wherein activation of the power switch generates a testing cycle which causes a testing surge of current to be generated within the installed electrical system when attached thereto;
a temperature sensor contained within the housing for monitoring the temperature at a location within the housing, the temperature sensor providing a temperature signal to the microcontroller indicative of the temperature at the location; and
a power supply contained within the housing and configured to receive a line signal from the installed electrical system, the power supply further providing a low voltage signal to the microcontroller indicative of the frequency of the line signal, wherein the microcontroller can operate as a counter to monitor the time the testing surge is present;
wherein the microcontroller will monitor the operation of the load circuit and the temperature sensor and will delay activation of the power switch if the temperature sensor indicates that the temperature at the location is above a predetermined temperature level, or the load circuit has operated outside a predetermined set of preferred operating parameters.

34. The portable handheld circuit breaker locator/tester of claim 33 where in the microcontroller will further insert a testing delay between testing cycles, the testing delay being a predetermined period of time.

35. The portable handheld circuit breaker locator/tester of claim 33 wherein the counter is used to determine if the load circuit has operated outside the predetermined set of preferred operating parameters.

36. The portable handheld circuit breaker locator/tester of claim 35 wherein the predetermined set of operating parameters comprise a combined predetermined amount of time the testing surge is present and number of test cycles within a the recent time period, and wherein the delay will continue for a predetermined period of time.

37. The portable handheld circuit breaker locator/tester of claim 35 wherein the predetermined set of operating parameters comprise a combined predetermined amount of time the testing surge is present and number of test cycles within a the recent time period, and wherein the delay will continue until the temperature sensor has confirmed that the temperature within the housing has dropped to below a predetermined target level which is different than the predetermined temperature level.
